(19) United States
(12) Patent Application Publication
(10) Pub. No.: US 2016/0268157 A1
(43) Pub. Date: Sep. 15, 2016

(54) LIFT PIN AND DISPLAY PANEL PRODUCTION EQUIPMENT

(71) Applicants: BOE TECHNOLOGY GROUP CO., LTD., BEIJING (CN); BEIJING BOE DISPLAY TECHNOLOGY CO., LTD., BEIJING (CN)

(72) Inventors: LEI GONG, BEIJING (CN); TAO WANG, BEIJING (CN); GUANGLONG GUO, BEIJING (CN); ZHENYONG DING, BEIJING (CN); ZHENYU ZHANG, BEIJING (CN)

(73) Assignees: BOE TECHNOLOGY GROUP CO., LTD., BEIJING (CN); BEIJING BOE DISPLAY TECHNOLOGY CO., LTD., BEIJING (CN)

(21) Appl. No.: 14/407,339

(22) PCT Filed: Apr. 22, 2014
(86) PCT No.: PCT/CN2014/075875

§ 371 Date: Dec. 11, 2014

(30) Foreign Application Priority Data
Sep. 17, 2013 (CN) 201310424982.2

(51) Int. Cl. H01L 21/687; H01J 37/32

(52) U.S. Cl. CPC H01L 21/68742; H01J 37/32009

(57) ABSTRACT

The present disclosure discloses a lift pin and a display panel production equipment, each of which reduces electrostatic ions located on a back side of a substrate and effectively avoids electrostatic ions and particles generated by a friction. The lift pin includes a body having a hollow structure, and at least one opening provided on at least one of a top end portion and a lateral side portion of the body. The opening controls gas flowing through the hollow structure of the body to blow out from the opening in order to remove static electricity between the lift pin and the adjacent equipment.

### CROSS-REFERENCE TO RELATED APPLICATION

This application is the U.S. national phase of PCT Application No. PCT/CN2014/075875 filed on Apr. 22, 2014, which claims priority to Chinese Patent Application No. 201310424982.2 filed on Sep. 17, 2013, the disclosures of which are incorporated in their entirety by reference herein.

### TECHNICAL FIELD

The present disclosure relates to the field of display technology, in particular to a lift pin and a display panel production equipment.

### BACKGROUND

In semiconductor and liquid crystal industries, in order to prevent the electrostatic ions, which are generated during transferring of a substrate, from damaging the product, plasma gas is usually applied to the substrate to neutralize the electrostatic ions.

In the liquid crystal industry, eliminating electrostatic effect by blowing the plasma gas is widely used for reducing and relieving the static electricity. Plasma gas apparatus is generally located above a stage. However, the electrostatic ions are generated mainly by a friction between the substrate and a lift pin, or generated by a friction between the substrate and the stage, or generated during transferring of the substrate. Thus, most of the electrostatic ions are located under the substrate.

As shown in FIG. 1, in the prior art, the plasma gas apparatus 10 is located above the stage 11. However, most of the electrostatic ions are located under the substrate 12 and above the stage. Thus, the lift pin structure in the prior art cannot properly remove the electrostatic ions on a back side of the substrate 12, and thereby causing a short circuit of a circuit and reducing a yield rate. Further, during an ascent of the lift pin 13, the lift pin is likely to have a friction with a stage passage and generate additional electrostatic ions and a great amount of particles.

As described above, the currently existed external plasma gas apparatus cannot properly remove the electrostatic ions.

### SUMMARY

The present disclosure provides a lift pin which reduces electrostatic ions located on a back side of a substrate and effectively avoid electrostatic ions and particles generated by a friction. The present disclosure also provides a display panel production equipment.

According to one embodiment of the present disclosure, a lift pin includes a body having a hollow structure, and at least one opening provided on at least one of a top end portion and a lateral side portion of the body. The opening controls gas flowing through the hollow structure of the body to blow out from the opening.

The lift pin according to the embodiment of the present disclosure has the hollow structure body. Thus, the gas, which can neutralize the electrostatic ions, can be sent to an inside portion of lift pin. Further, the lift pin has the opening at the lateral side portion and/or the top end portion of the body. Thus, the gas flowing through the inside portion of the lift pin body can blow out from the opening. With this configuration, the electrostatic ions generated between the stage and the back side of the substrate can be effectively removed, and product yield can be improved.

Alternatively, multiple openings may be provided on the lateral side portion of the body.

In this configuration, the multiple openings provided on the lateral side portion of the body blow out the gas. Thus, electrostatic ions and a great amount of particles generated by a friction between the lift pin and the stage during an ascent of the lift pin can be effectively avoided.

Alternatively, the openings may have the same dimension.

With this configuration, the gas can be uniformly blown out from the lift pin and a blowing amount of the gas can be easily controlled. This configuration eases a control of an interaction force between the side portion of the lift pin and the stage passage during an ascent of the lift pin. Thus, the friction between the lift pin and the stage during the ascent of the lift pin can be effectively avoided.

Alternatively, the openings provided on the lateral side portion of the body may be disposed symmetrically with respect to a longitudinal center axis of the body.

With this configuration, the openings symmetrically provided on the lateral side portion of the body can control the interaction force between each of the two lateral sides of the lift pin and the stage passage to maintain the same. Thus, the friction between the lift pin and the stage during the ascent of the lift pin can be easily controlled.

Alternatively, the opening of the lift pin has a circular shape.

With this configuration, a design and manufacturing of the opening can be eased by using the circular shape.

Alternatively, the opening provided on the top end portion of the body may have an area equal to or less than 1.7671 square millimeters.

In the lift pin, a lift pin cap is disposed on the top end portion of the lift pin. Thus, the opening provided on the top end portion of the lift pin should not be to too large. When the opening provided on the top end portion of the body has an area equal to or less than 1.7671 square millimeters, the electrostatic ions on the back side of the substrate can be effectively reduced.

Alternatively, the opening provided on the lateral side portion of the body may have an area equal to or less than 0.7854 square millimeters.

In order to ensure strength of the lift pin, the opening provided on the lateral side portion of the lift pin should not be too large. When the opening provided on the lateral side portion of the body has an area equal to or less than 0.7854 square millimeters, the electrostatic ions and the particles generated by the friction can be further effectively avoided.

Alternatively, the lift pin body having a hollow structure has a cylinder shape.

With this configuration, a positioning design of the cylinder-shaped lift pin on the stage member can become easy and convenient. At the same time, a gas flow in the hollow structure of the cylinder-shaped lift pin can be easily controlled.

According to another embodiment of the present disclosure, a display panel production equipment includes a plasma gas apparatus and the above-described lift pin. The plasma gas apparatus has gas passage members corresponding to the lift pins one by one. The gas passage member outputs plasma gas to the corresponding lift pin. The plasma gas blows out from the opening provided on the body.

In the display panel production equipment provided by the above-described embodiment, the display panel production equipment includes above-described lift pin. Thus, the display panel production equipment can effectively reduce the electrostatic ions on the back side of the substrate, and effectively avoid electrostatic ions and the particles generated by the friction.

Alternatively, the lift pin may be seamlessly connected with the corresponding gas passage member.

With this seamless connection configuration, the plasma gas can be completely input to the inside portion of the lift pin and gas leakage can be avoided. Thus, the gas amount input to the inside portion of the lift pin can be accurately controlled.

Alternatively, the gas passage member may be a gas pipe.

When the gas passage member is the gas pipe, the seamless connection between the gas pipe and the lift pin can be easily achieved compared with other structure of the gas passage member. Further, the gas pipe can be easily and conveniently disposed.

### BRIEF DESCRIPTION OF THE DRAWINGS

FIG. 1 is a schematic diagram showing a structure of a display panel production equipment in the related art;

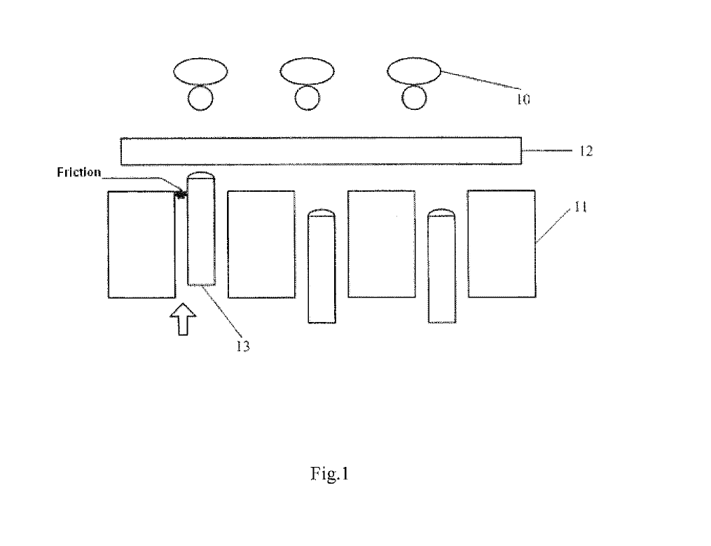

FIG. 2 is a schematic diagram showing a structure of a lift pin according to an embodiment of the present disclosure; and

FIG. 3 is a schematic diagram showing a structure of a display panel production equipment according to an embodiment of the present disclosure.

### DETAILED DESCRIPTION

The present disclosure discloses a lift pin and a display panel production equipment, each of which reduces electrostatic ions on a back side of a substrate and effectively avoids electrostatic ions and particles generated by a friction.

The following will describe embodiments of the present disclosure with reference to the accompanying drawings.

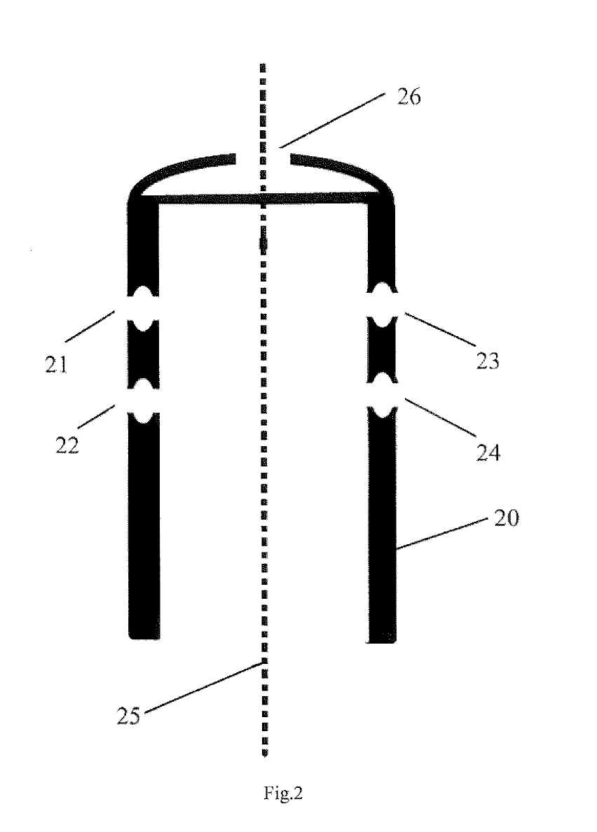

As shown in FIG. 2, an embodiment of the present disclosure provides a lift pin 20 used in a production of a display panel. The lift pin 20 has a hollow structure body. An opening is provided on a top end portion and/or a lateral side portion of the body. The opening controls gas, which flows through the hollow structure of the body, to blow out from the opening. The opening provided on the lateral side wall of the lift pin relieves the friction between the lateral side portion of the lift pin and an adjacent equipment. Thus, the static electricity between the lift pin and the adjacent equipment can be eliminated. At the same time, the gas flow blown out from the lateral side portion can remove dust particles. The opening provided on the top end portion of the lift pin can effectively reduce the electrostatic ions on the back side of the substrate, and at the same time, can remove the dust particles.

The lift pin 20 has multiple openings provided on the lateral side portion. In FIG. 2, multiple openings 21, 22, 23, 24 are provided on the lateral side portion of the lift pin. The openings provided on the lateral side portion of the lift pin are not limited to the openings described in the embodiment, and the number of openings can be properly defined according to an actual production needs.

The openings 21, 22, 23, 24 have the same dimension.

The openings 21 and 23 are disposed symmetrically with respect to a longitudinal center axis 25 of the lift pin 20, and the openings 22 and 24 are disposed symmetrically with respect to the longitudinal center axis 25 of the lift pin 20.

Each of the openings 21, 22, 23, 24 has a circular shape. Alternatively, each of the openings 21, 22, 23, 24 may have a different shape, not limited to the circular shape according to the present disclosure.

The opening 26 provided on the top end portion has an area equal to or less than 1.7671 square millimeters. FIG. 2 only shows the opening 26 provided on the top end portion of the lift pin. The opening provided on the top end portion is not limited to the opening provided in the embodiment of the present disclosure. Multiple openings may be provided on the top end portion of the lift pin according to actual production needs. The opening provided on the top end portion may have the circular shape. When the opening provided on the top end portion has the circular shape, a radius of the opening is equal to or less than 0.75 millimeter. Further, the openings may have different shapes.

Each of the openings 21, 22, 23, 24 provided on the lateral side portion has an area equal to or less than 0.7854 square millimeters. A radius of each opening 21, 22, 23, 24 is equal to or less than 0.5 millimeter.

The lift pin 20 has a hollow cylinder-shaped body. Alternatively, the lift pin 20 may have a hollow rectangular parallelepiped shape, or other shapes, which is not limited to the cylinder shape described in the embodiment of the present disclosure.

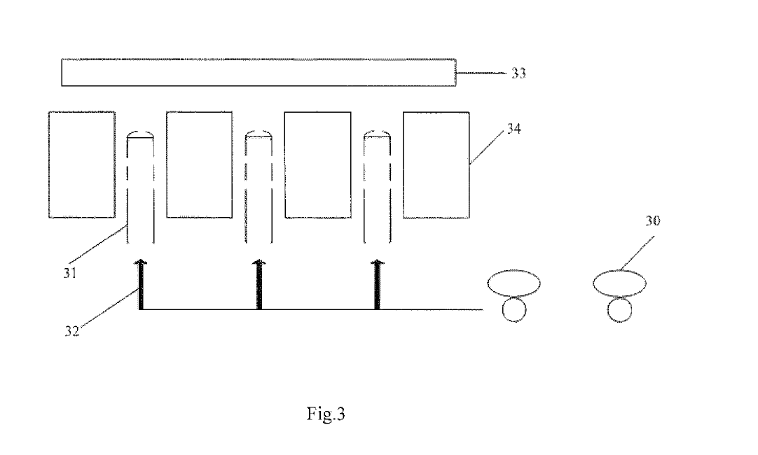

As shown in FIG. 3, an embodiment of the present disclosure provides a display panel production equipment. The equipment includes a plasma gas apparatus 30 and the multiple lift pins 31. The number of the lift pins can be set based on the actual needs of the production equipment. The plasma gas apparatus 30 has gas passage members 32, which correspond to the lift pins 31 one by one. The gas passage members 32 output the plasma gas to the corresponding lift pins 31, and then, the plasma gas, which is output to the lift pin 31, blows out from the openings provided on the lift pin 31.

The lift pin 31 is seamlessly connected with the corresponding gas passage member 32. Similarly, each of the lift pins included in the display panel production equipment is seamlessly connected with the corresponding gas passage member. FIG. 3 only shows a position of the gas passage member corresponding to each lift pin, but not shows the gas passage member connected with the lift pin. The gas passage member 32 is a gas pipe.

As shown in FIG. 3, different from a conventional lift pin, the lift pin 31 according to the embodiment of the present disclosure has a hollow structure, and plasma gas is input to the inside portion of the lift pin 31. Further, the openings through which the plasma gas blows out are provided on the body of the lift pin 31. Thus, the plasma gas blown out from the openings of the lift pin 31 can remove the electrostatic ions on the stage 34 and on the back side of the substrate 33. At the same time, the openings symmetrically disposed on the lateral side portion of the lift pin can relieve the friction between the lift pin and the stage passage during an ascent of the lift pin. Thereby, the electrostatic ions and a great amount of particles generated by the friction can be effectively avoided.

As described above, the embodiment of the present disclosure provides a lift pin and a display panel production equipment. The lift pin includes a body having a hollow structure, and at least one opening provided on at least one of a top end portion and a lateral side portion of the body. The opening controls gas flowing through the hollow structure of the body to blow out from the opening in order to reduce the static electricity generated during a production of the substrate. Thus, electrostatic ions and particles generated by the friction can be effectively avoided.

Obviously, those skilled in the art can change and modify present disclosure in various ways without departing from a spirit and a scope of the present disclosure. Thus, when the change and modification of the present disclosure belong to a scope of the claims of the present disclosure and their equivalents, the present disclosure also intends to include these changes and modifications.

What is claimed is:

1. A lift pin comprising:
a body having a hollow structure; and
at least one opening provided on at least one of a top end portion and a lateral side portion of the body, the opening controlling gas flowing through the hollow structure of the body to blow out from the opening.

2. The lift pin according to claim 1, wherein a plurality of the openings are provided on the lateral side portion of the body.

3. The lift pin according to claim 1, wherein the openings have a same dimension.

4. The lift pin according to claim 2, wherein the openings have a same dimension.

5. The lift pin according to claim 1, wherein the openings provided on the lateral side portion of the body are disposed symmetrically with respect to a longitudinal center axis of the body.

6. The lift pin according to claim 1, wherein the opening has a circular shape.

7. The lift pin according to claim 1, wherein the opening provided on the top end portion of the body has an area equal to or less than 1.7671 square millimeters.

8. The lift pin according to claim 1, wherein the opening provided on the lateral side portion of the body has an area equal to or less than 0.7854 square millimeters.

9. The lift pin according to claim 1, wherein the body having the hollow structure has a cylinder shape.

10. A display panel production equipment comprising
a plasma gas apparatus; and
the lift pin according to claim 1,
wherein the plasma gas apparatus has a gas passage member corresponding to the lift pin, the gas passage member outputs plasma gas to the corresponding lift pin, and the plasma gas blows out from the opening provided on the body.

11. The display panel production equipment according to claim 10, wherein the lift pin is seamlessly connected with the corresponding gas passage member.

12. The display panel production equipment according to claim 10, wherein the gas passage member is a gas pipe.

13. The display panel production equipment according to claim 10, wherein a plurality of the openings are provided on the lateral side portion of the body.

14. The display panel production equipment according to claim 10, wherein the openings have a same dimension.

15. The display panel production equipment according to claim 10, wherein the openings provided on the lateral side portion of the body are disposed symmetrically with respect to a longitudinal center axis of the body.

16. The display panel production equipment according to claim 10, wherein the opening has a circular shape.

17. The display panel production equipment according to claim 10, wherein the opening provided on the top end portion of the body has an area equal to or less than 1.7671 square millimeters.

18. The display panel production equipment according to claim 10, wherein the opening provided on the lateral side portion of the body has an area equal to or less than 0.7854 square millimeters.

19. The display panel production equipment according to claim 10, wherein the body having the hollow structure has a cylinder shape.
